(19) United States
(12) Patent Application Publication
(10) Pub. No.: US 2012/0199198 A1
(43) Pub. Date: Aug. 9, 2012

(54) STRUCTURED FILM AND ARTICLES MADE THEREFROM

(76) Inventors: Timothy J. Hebrink, Scandia, MN (US); James M. Jonza, Woodbury, MN (US)

(21) Appl. No.: 13/499,763

(22) PCT Filed: Oct. 18, 2010
(86) PCT No.: PCT/US10/53039

§ 371 Date: Apr. 2, 2012

Related U.S. Application Data
(60) Provisional application No. 61/254,896, filed on Oct. 26, 2009.

(51) Int. Cl. H01L 31/0232; F24J 2/08

(52) U.S. Cl. 136/259; 126/698

(57) ABSTRACT

Solar energy collection assemblies comprising a surface structured polyurethane layer. The structured polyurethane layer includes a cross-linkable reaction mixture and at least one UV stabilizer. The cross-linkable reaction mixture includes a polyol, a polyisocyanate and optionally a catalyst.

### FIELD OF THE DISCLOSURE

The present disclosure relates to structured films, methods of making structured films and devices utilizing structured films.

### BACKGROUND

Energy conversion devices used in solar applications convert the sun's energy to another energy form, for example electricity or heat. Therefore, the efficiency of the device is increased if the solar rays are effectively transmitted to the energy conversion device. Therefore, it is desirable for an antireflective surface to be placed between the energy conversion device and the sun to reduce surface reflections and increase transmission.

### SUMMARY

The present application is directed to an energy conversion assembly. The energy conversion assembly comprises a solar energy conversion device and a non-concentrating structured layer adjacent the energy conversion device. The structured layer comprises a crosslinked reaction mixture and at least one UV stabilizer. The mixture comprises a polyol, a polyisocyanate, and a catalyst.

### BRIEF DESCRIPTION OF THE DRAWINGS

FIG. 1 is a graphical representation of data as shown in the Example section herein.

FIG. 2 is an elevated view of a first embodiment of the present invention.

FIG. 3 is an elevated view of a second embodiment of the present invention.

FIG. 4 is an elevated view of a third embodiment of the present invention.

FIG. 5 is an elevated view of a fourth embodiment of the present invention.

### DETAILED DESCRIPTION

The term “energy conversion device” as used herein refers to a device that converts a first energy form to a second energy form.

The term “polyurethane” as used herein refers to polymers prepared by the condensation polymerization of hydroxyl-functional materials (materials containing hydroxyl groups —OH) with isocyanate-functional materials (materials containing isocyanate groups

—NCO) and therefore contain urethane linkages (—O(CO)—NH—), where (CO) refers to a carbonyl group (C═O).

The term “structured” as used herein, refers to a surface, the surface comprising a series of features and wherein at least one of the feature dimensions (height, width and length) is greater than 1 micrometer. Two or even all three of the feature dimensions (height, width, length) may be greater than 1 micrometer. Typically the structures are less than 1 millimeter in at least one dimension, generally less than 1 millimeter in all of the feature dimensions.

The term “non-concentrating” as used herein, refers to incoming light, such as sunlight, is maintained in a relatively uniform intensity and does not focus light on to a defined target area.

The term “adhesive” as used herein refers to polymeric compositions useful to adhere together two adherends. Examples of adhesives are heat activated adhesives, structural adhesives and pressure sensitive adhesives.

Heat activated adhesives are non-tacky at room temperature but become tacky and capable of bonding to a substrate at elevated temperatures. These adhesives usually have a Tg or melting point (Tm) above room temperature. When the temperature is elevated above the Tg or Tm, the storage modulus usually decreases and the adhesive become tacky.

Structural adhesives refer to adhesives that can bond other high strength materials (e.g., wood, composites, or metal) so that the adhesive bond strength is in excess of 6.0 MPa (1000 psi).

Pressure sensitive adhesive (PSA) compositions are well known to those of ordinary skill in the art to possess properties including the following: (1) aggressive and permanent tack, (2) adherence with no more than finger pressure, (3) sufficient ability to hold onto an adherend, and (4) sufficient cohesive strength to be cleanly removable from the adherend. Materials that have been found to function well as PSAs are polymers designed and formulated to exhibit the requisite viscoelastic properties resulting in a desired balance of tack, peel adhesion, and shear holding power. Obtaining the proper balance of properties is not a simple process.

The energy conversion device of the present application may be exposed to an outdoor environment. The structured surface especially may have weathering properties to combat, for example, exposure to heat and ultraviolet (UV) radiation. This is particularly important for uses in solar energy conversion devices.

The energy conversion device may be any item that converts one form of energy (for example solar energy such as heat or radiation) to another form of energy (for example electricity). In some embodiments, the energy conversion device is a solar energy conversion device, for example a thermal absorption device to convert solar radiation into heat, or a solar photovoltaic cell to convert solar irradiation to electric current.

Solar energy conversion devices are used in a wide array of applications, both earth-bound applications and space-based applications. In some embodiments, the solar energy conversion device may be attached to a vehicle, such as an automobile, a plane, a train or a boat. Many of these environments are very hostile to organic polymeric materials.

Solar energy conversion devices having flat glass or polymer front side layers typically lose 3-5% of available solar energy due to front side surface reflections. The non-concentrating structured surface layer of this invention minimizes surface reflections. Incident solar rays are partially reflected off the sloped surfaces of the structured surface. However, these partially reflected solar rays reflect onto the adjacent surface structure where they are either refracted directly to the solar energy conversion device, or are totally internally reflected to the solar energy conversion device. Almost all of the incident solar rays eventually reach the solar energy conversion device, thus increasing its efficiency.

A non-concentrating structured layer is adjacent the energy conversion device. For the purpose of the present application, adjacent includes embodiments having one or more layers between the structured layer and the energy conversion device, including, for example, air gaps, polymer layers or glass layers. Generally, the structured layer is less than 1 meter from the energy conversion device. In some embodiments, the structured layer is in contact with the energy conversion device.

The structured layer includes a structured surface comprising a series of structures. The structured layer may be a single material or may be a multilayer construction, where the structured layer comprises one material formulation, and a base film and adhesive comprise different material formulations. Additionally, the film and adhesive layers could themselves comprise multiple layers. Generally, the structured layer has a structured surface wherein, wherein a substantial portion of reflected light intersects another structure on the surface. In some embodiments, the series of structures comprises a series of essentially parallel peaks separated by a series of essentially parallel valleys. In cross-section the structured layer may assume a variety of wave forms. For example, the cross section may assume a symmetric saw tooth pattern in which each of the peaks are identical as are each of the valleys; a series of parallel peaks that are of different heights, separated by a series of parallel valleys; or a saw tooth pattern of alternating, parallel, asymmetric peaks separated by a series of parallel, asymmetric valleys. In some embodiments, the peaks and valleys are continuous and in other embodiments a discontinuous pattern of peaks and valleys is also contemplated. Thus, for example, the peaks and valleys may terminate for a portion of the article. The valleys may either narrow or widen as the peak or valley progresses from one end of the article to the other. Still further, the height and/or width of a given peak or valley may change as the peak or valley progresses from one end of the article to the other.

In some embodiments, the structured surface is opposite the energy conversion device, and the structured surface is antireflective. An antireflective, structured surface means, for the purpose of the present application, that reflection, averaged over all angles of incidence, is less than it would be on a corresponding flat surface, for example is less than 50% of the reflection off the flat surface, and in specific embodiments less than 80% of the reflection off the flat surface.

The dimensions of the peaks generally have a height of at least about 10 micrometers (0.0004 inches). In another embodiment, peaks have a height of as much as about 250 micrometers (0.010 inches). In one embodiment, the peaks are at least about 20 micrometers (0.0008 inches) high, and in another embodiment, the peaks are as much as about 150 micrometers (0.006 inches) high. The peak-to-peak spacing between adjacent peaks is generally at least about 10 micrometers (0.0004 inches). In another embodiment, the spacing is as much as about 250 micrometers (0.010 inches. In one embodiment, the spacing is at least about 20 micrometers (0.0008 inches), and in some embodiments, the spacing is as much as about 150 micrometers (0.006 inches). The included angle between adjacent peaks can also vary. The valleys may be flat, round, parabolic, or V-shaped. The peaks are generally V-shaped and have an apex angle of less than 60 degrees, in some embodiments less than 50 degrees and in specific embodiments less than 40 degrees. However, the present application is also directed to peaks having a radius of curvature at the tip, and such an embodiment has an apex angle measured by the best fit line to the sides.

In some embodiments, the series of structures are non-uniform structures. For example, the structures differ in height, base width, pitch, apex angle, or other structural aspect. In such embodiments, the slope of the structures from the plane of the surface averages over the surface less than 30 degrees from normal. In other embodiments, the structures are substantially symmetric in one dimension around a perpendicular to the surface.

The structured surface comprises a structured polyurethane layer. This polyurethane layer is prepared from the condensation polymerization of a reaction mixture that comprises a polyol, a polyisocyanate, and a catalyst. The reaction mixture may also contain additional components which are not condensation polymerizable, and generally contains at least one UV stabilizer. As will be described below, the condensation polymerization reaction, or curing, generally is carried out in a mold or tool to generate the structured surface in the cured surface.

Because the polyurethane polymers described in this disclosure are formed from the condensation reaction of a polyol and a polyisocyanate they contain at least polyurethane linkages. The polyurethane polymers formed in this disclosure may contain only polyurethane linkages or they may contain other optional linkages such as polyurea linkages, polyester linkages, polyamide linkages, silicone linkages, acrylic linkages, and the like. As described below, these other optional linkages can appear in the polyurethane polymer because they were present in the polyol or the polyisocyanate materials that are used to form the polyurethane polymer. The polyurethane polymers of this disclosure are not cured by free radical polymerizations. For example, polyurethane oligomeric molecules with vinylic or other free radically polymerizable end groups are known materials, and polymers formed by the free radical polymerization of these molecules are sometimes referred to as “polyurethanes”, but such polymers are outside of the scope of this disclosure.

Typically the structured polyurethane layer is of a sufficient size to produce the desired optical effect. The polyurethane layer is generally no more than 10 millimeters thick, typically much thinner. For economical reasons, it is generally desirable to use a structured polyurethane layer which is as thin as possible. It may be desirable to maximize the amount of polyurethane material which is contained in the structures and to minimize the amount of polyurethane material that forms the base of the structured polyurethane layer but is not structured. In some instances this base portion is sometimes referred to as “the land” as it is analogous to the land from which mountains arise.

A wide variety of polyols may be used. The term polyol includes hydroxyl-functional materials that generally comprise at least 2 terminal hydroxyl groups and may be generally described by the structure HO—B—OH, where the B group may be an aliphatic group, an aromatic group, or a group containing a combination of aromatic and aliphatic groups, and may contain a variety of linkages or functional groups, including additional terminal hydroxyl groups. Typically the HO—B—OH is a diol or a hydroxyl-capped prepolymer such as a polyurethane, polyester, polyamide, silicone, acrylic, or polyurea prepolymer.

Examples of useful polyols include, but are not limited to, polyester polyols (such as lactone polyols), polyether polyols (such as polyoxyalkylene polyols), polyalkylene polyols, mixtures thereof, and copolymers therefrom. Polyester polyols are particularly useful. Among the useful polyester polyols are linear and non-linear polyester polyols including, for example, those made from polyethylene adipate, polybutylene succinate, polyhexamethylene sebacate, polyhexamethylene dodecanedioate, polyneopentyl adipate, polypropylene adipate, polycyclohexanedimethyl adipate, and poly ε-caprolactone. Particularly useful are aliphatic polyester polyols available from King Industries, Norwalk, Conn., under the trade name “K-FLEX” such as K-FLEX 188 or K-FLEX A308.

Where HO—B—OH is a hydroxyl-capped prepolymer, a wide variety of precursor molecules can be used to produce the desired HO—B—OH prepolymer. For example, the reaction of polyols with less than stoichiometric amounts of diisocyanates can produce a hydroxyl-capped polyurethane prepolymer. Examples of suitable diisocyanates include, for example, aromatic diisocyanates, such as 2,6-toluene diisocyanate, 2,5-toluene diisocyanate, 2,4-toluene diisocyanate, m-phenylene diisocyanate, p-phenylene diisocyanate, methylene bis(o-chlorophenyl diisocyanate), methylenediphenylene-4,4′-diisocyanate, polycarbodiimide-modified methylenediphenylene diisocyanate, (4,4′-diisocyanato-3,3′,5,5′-tetraethyl)biphenylmethane, 4,4′-diisocyanato-3,3′-dimethoxybiphenyl, 5-chloro-2,4-toluene diisocyanate, 1-chloromethyl-2,4-diisocyanato benzene, aromatic-aliphatic diisocyanates such as m-xylylene diisocyanate, tetramethyl-m-xylylene diisocyanate, aliphatic diisocyanates, such as 1,4-diisocyanatobutane, 1,6-diisocyanatohexane, 1,12-diisocyanatododecane, 2-methyl-1,5diisocyanatopentane, and cycloaliphatic diisocyanates such as methylene-dicyclohexylene-4,4′-diisocyanate, and 3-isocyanatomethyl-3,5,5-trimethyl-cyclohexyl isocyanate (isophorone diisocyanate). For reasons of weatherability, generally aliphatic and cycloaliphatic diisocyanates are used.

An example of the synthesis of a HO—B—OH prepolymer is shown in Reaction Scheme 1 (where (CO) represents a carbonyl group C═O) below:

2HO—R¹—OH+OCN—R²—NCO→HO—R¹—O—[(CO)N—R²—N(CO)O—R¹—O—]ₙH Reaction Scheme 1

where n is one or greater, depending upon the ratio of polyol to diisocyanate, for example, when the ratio is 2:1, n is 1. Similar reactions between polyols and dicarboxylic acids or dianhydrides can give HO—B—OH prepolymers with ester linking groups.

Polyols with more than two hydroxyl groups per molecule will lead to a crosslinked resin upon reaction with di or higher functionality isocyanates. Crosslinking prevents creep of the formed polymer, and helps maintain the desired structure. Typically the polyol is an aliphatic polyester polyol such as those available from King Industries, Norwalk, Conn., under the trade name “K-FLEX” such as K-FLEX 188 or K-FLEX A308.

A wide variety of polyisocyanates may be used. The term polyisocyanate includes isocyanate-functional materials that generally comprise at least 2 terminal isocyanate groups, such as diisocyanates that may be generally described by the structure OCN—Z—NCO, where the Z group may be an aliphatic group, an aromatic group, or a group containing a combination of aromatic and aliphatic groups. Examples of suitable diisocyanates include, for example, aromatic diisocyanates, such as 2,6-toluene diisocyanate, 2,5-toluene diisocyanate, 2,4-toluene diisocyanate, m-phenylene diisocyanate, p-phenylene diisocyanate, methylene bis(o-chlorophenyl diisocyanate), methylenediphenylene-4,4′-diisocyanate, polycarbodiimide-modified methylenediphenylene diisocyanate, (4,4′-diisocyanato-3,3′,5,5′-tetraethyl)biphenylmethane, 4,4′-diisocyanato-3,3′-dimethoxybiphenyl, 5-chloro-2,4-toluene diisocyanate, 1-chloromethyl-2,4-diisocyanato benzene, aromatic-aliphatic diisocyanates such as m-xylylene diisocyanate, tetramethyl-m-xylylene diisocyanate, aliphatic diisocyanates, such as 1,4-diisocyanatobutane, 1,6-diisocyanatohexane, 1,12-diisocyanatododecane, 2-methyl-1,5diisocyanatopentane, and cycloaliphatic diisocyanates such as methylene-dicyclohexylene-4,4′-diisocyanate, and 3-isocyanatomethyl-3,5,5-trimethyl-cyclohexyl isocyanate (isophorone diisocyanate). For reasons of weatherability, generally aliphatic and cycloaliphatic diisocyanates are used. Some degree of crosslinking is useful in maintaining the desired structured surface. One approach is to use polyisocyanates with a higher functionality than 2.0. One particularly suitable aliphatic polyisocyanate is DESMODUR N3300A commercially available from Bayer, Pittsburgh, Pa.

In some embodiments, the structured layer has a variable crosslink density throughout the thickness of the layer. For example, there may be a higher crosslink density at the surface of the structured layer. The crosslink density may be increased at the surface of the structured surface film using electron beam irradiation at relatively low voltage such as 100 kV to 150 kV.

The reactive mixture used to form the structured polyurethane layer also contains a catalyst. The catalyst facilitates the condensation reaction between the polyol and the polyisocyanate. Conventional catalysts generally recognized for use in the polymerization of urethanes may be suitable for use with the present disclosure. For example, aluminum-based, bismuth-based, tin-based, vanadium-based, zinc-based, or zirconium-based catalysts may be used. Tin-based catalysts are particularly useful. Tin-based catalysts have been found to significantly reduce the amount of outgassing present in the polyurethane. Most desirable are dibutyl tin compounds, such as dibutyltin diacetate, dibutyltin dilaurate, dibutyltin diacetylacetonate, dibutyltin dimercaptide, dibutyltin dioctoate, dibutyltin dimaleate, dibutyltin acetonylacetonate, and dibutyltin oxide. The dibutyltin dilaurate catalyst DABCO T-12, commercially available from Air Products and Chemicals, Inc., Allentown, Pa. is particularly suitable. The catalyst is generally included at levels of at least 25 ppm or even 1000 ppm or greater. Approximately 300 ppm has provided for reasonable curing times.

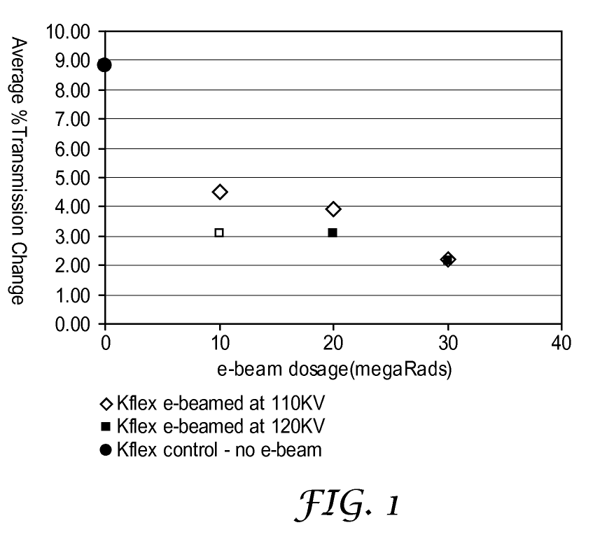

Alternatively, the polyol and polyisocyanate reaction may proceed without a catalyst, and the crosslinking accelerated by free radicals formed via electron beam irradiation. This may be advantageous, in that the catalysts may contribute to oxidative and photo-degradation of the polyurethane polymer. In another embodiment, the reactive mixture is polymerized with the above preferred catalysts, and then further cross-linked with electron beam irradiation. Higher cross-link densities achieved with electron beam irradiation increase the durability of the polyurethane, especially to abrasion, such as from falling sand as shown in FIG. 1. Electron beam irradiation can be controlled to provide higher cross-link density at the surface of the polyurethane structured surface than in the bulk of the polyurethane article. High cross-link density has the desirable effect of minimizing transmission losses from abrasion. For example, exposure of surface structured aliphatic polyurethanes to 30 megarads dosage at 120 kV decreases transmission losses to less than 3%. Transmission increases of 4-5% have been measured with the exemplified surface structures over flat glass surfaces before abrasion. Since the demonstrated benefit of the surface structure is to provide higher transmission than flat glass, it is desirable to have transmission losses no greater than 3% from abrasion. Exemplary highly cross-linked surface structured polyurethanes of this invention maintain higher transmission than flat glass after abrasion from falling sand.

The aliphatic polyurethanes show good stability to ultraviolet weathering, but the addition of UV stabilizers can further improve their stability when exposed to the environment. Examples of suitable UV stabilizers include ultraviolet absorbers (UVAs), Hindered Amine Light Stabilizers (HALS), and antioxidants. It has been found useful to choose additives that are soluble in the reactive mixture, especially in the polyol. Benzotriazole UVAs such as the compounds TINUVIN P, 213, 234, 326, 327, 328, and 571 available from Ciba, Tarrytown, N.Y.; hydroxylphenyl triazines such as TINUVIN 400 and 405 available from Ciba, Tarrytown, N.Y.; HALS such as TINUVIN 123, 144, 622, 765, 770 available from Ciba, Tarrytown, N.Y.; and the antioxidants IRGANOX 1010, 1135 and 1076 available from Ciba, Tarrytown, N.Y., are particularly useful. The material TINUVIN B75, a product containing UVA, HALS and antioxidant available from Ciba, Tarrytown, N.Y. is also suitable.

The reactive mixture used to form the structured polyurethane layer may also contain additional additives if desired, as long as the additive does not interfere with the urethane polymerization reaction or adversely affect the optical properties of the formed structured polyurethane layer. Additives may be added to aid the mixing, processing, or coating of the reactive mixture or to aid the final properties of the formed structured polyurethane layer. Examples of additives include: particles, including nanoparticles or larger particles; mold release agents; low surface energy agents; antimildew agents; antifungal agents; antifoaming agents; antistatic agents; and coupling agents such as amino silanes and isocyanato silanes. Combinations of additives can also be used.

The structured surface may be readily manufactured by a variety of techniques. For example, the structure may be imparted during the manufacture. In one approach, the polymer for the structured surface is extruded or coated. The structured surface may be formed by embossing techniques utilizing heat, vacuum and/or pressure. In some embodiments it may be desirable to apply the reactive mixture to the structuring tool. Other techniques are also possible and will be readily thought of by those skilled in the art.

In some embodiments the structured film is prepared by applying a reactive mixture layer to a substrate, such as the energy conversion device, and creating the structured polyurethane layer on the substrate. The reactive mixture may be cured directly to the substrate. This process can be achieved in a variety of different ways that typically will include the steps of supplying a transparent substrate, priming the transparent substrate to promote adhesion, preparing a reactive mixture, applying the reactive mixture to the transparent substrate, applying a structuring tool to the reactive mixture, polymerizing the reactive mixture and removing the tool to form the structured polyurethane layer on the transparent substrate.

The structured polyurethane layer may be adhered to the energy conversion device through the use of an adhesive. The adhesive may take a variety of forms including pressure sensitive adhesives, heat activated adhesives as well as structural adhesives. It is desirable to select an adhesive which will adhere the structured polyurethane layer to the transparent substrate without interfering with the optical properties of the structured layer. Generally, useful structural adhesives contain reactive materials that cure to form a strong adhesive bond to the transparent substrate and the structured polyurethane layer. The structural adhesive may cure spontaneously upon mixing (such as a 2 part epoxy adhesive) or upon exposure to air (such as a cyanoacrylate adhesive) or curing may be effected by the application of heat or radiation (such as UV light). Examples of suitable structural adhesives include epoxies, acrylates, cyanoacrylates, urethanes, and the like. In some embodiments it may be desirable to use the same reactive mixture use to prepare the structured polyurethane layer as the adhesive. One advantage is the compatibility the cured polyurethane layer can have with the reactive mixture used to form it.

Examples of suitable heat activated adhesives and pressure sensitive adhesives include for example, natural rubber adhesives, synthetic rubber adhesives, styrene block copolymer adhesives, polyvinyl ether adhesives, acrylic adhesives, polyolefin and olefin copolymer adhesives, silicone adhesives, urethane adhesives or urea adhesives.

The adhesive, whether structural, heat activated or pressure sensitive, can be applied either to the transparent substrate or to the cured structured polyurethane layer. The adhesive can be applied through a variety of coating techniques such as gravure coating, curtain coating, slot coating, spin coating, screen coating, transfer coating, brush or roller coating, spray coating, and inkjet printing, hot melt coating, and the like to form an adhesive layer. The adhesive layer may be continuous or discontinuous. If a heat activated adhesive is used, heat can be applied to enhance the tack of the adhesive layer. If the adhesive layer is present on the transparent substrate, the cured structured polyurethane layer is applied to the adhesive layer. If the adhesive layer is present on the cured structured polyurethane layer, the transparent substrate is contacted to the adhesive layer. In some embodiments it may also be desirable to apply adhesive to both the transparent substrate surface and to the cured structured polyurethane layer surface.

In some embodiments, a primer is used to improve adhesion to the substrate. Amino propyl silane primers such as available from Dow Corning and Momentive Performance Materials can be used to improve adhesion of the cross-linked polyurethane to glass.

In another embodiment, the structured polyurethane layer may be adhered to the energy conversion device by a liquid. In this embodiment, the surface interaction of the liquid to the substrate and to the structured layer should be chosen for good wetting of both surfaces. This approach is especially useful if easy removal of the structured polyurethane layer is desired at some future point in time. The choice of suitable liquids would also take into consideration: low evaporation rate, inertness with respect to the structured layer and substrate, UV stability, UVAs, HALS and antioxidants, and antistats.

Additionally, a plurality of structured polyurethane layers can be prepared on a single transparent substrate or a plurality of structured substrates using the techniques in which the reactive mixture is either coated onto the substrate or onto the tool and the substrate and the tool are brought together and the reactive mixture cured to form the structured polyurethane layer. Such a process could be done in a batchwise or in a continuous fashion. An example of a continuous process would be to use a coater, such as a notch bar coater, using a plurality of transparent substrates as the bottom layer and a tooling film as the top layer. The reactive mixture could be introduced continuously onto the transparent substrate layer and tooling film pressed onto this coating as the bottom layer is passed through the coater.

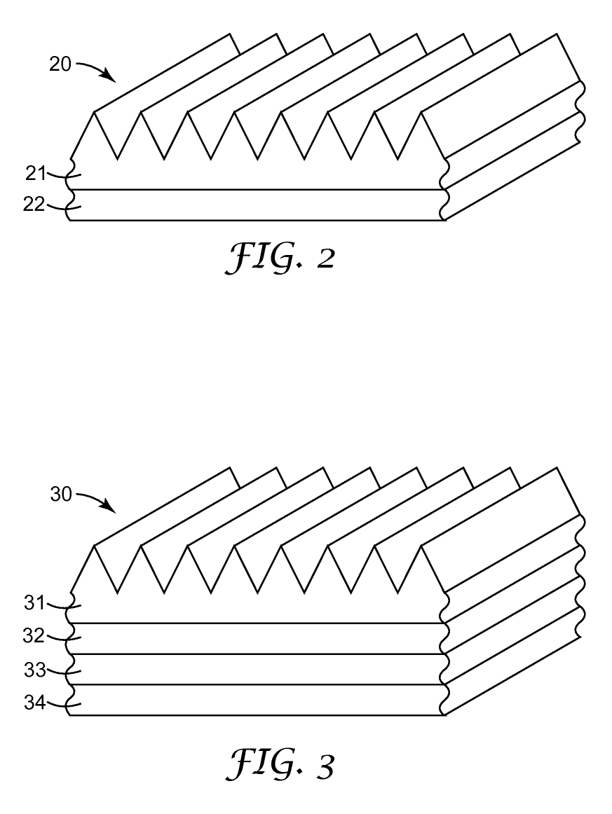

FIG. 2 shows one embodiment of the present application. The assembly 20 comprises a structured layer 21 and an energy conversion device 22. The structured layer 21 is in contact with the energy conversion device 22, and in some embodiments was cured directly to the energy conversion device 22. Another embodiment is shown in FIG. 3. Assembly 30 comprises a structured layer 31, a film layer 32, an adhesive layer 33, and an energy conversion device 34. In such embodiments, the energy conversion device 22 and 34 may be a photovoltaic cell.

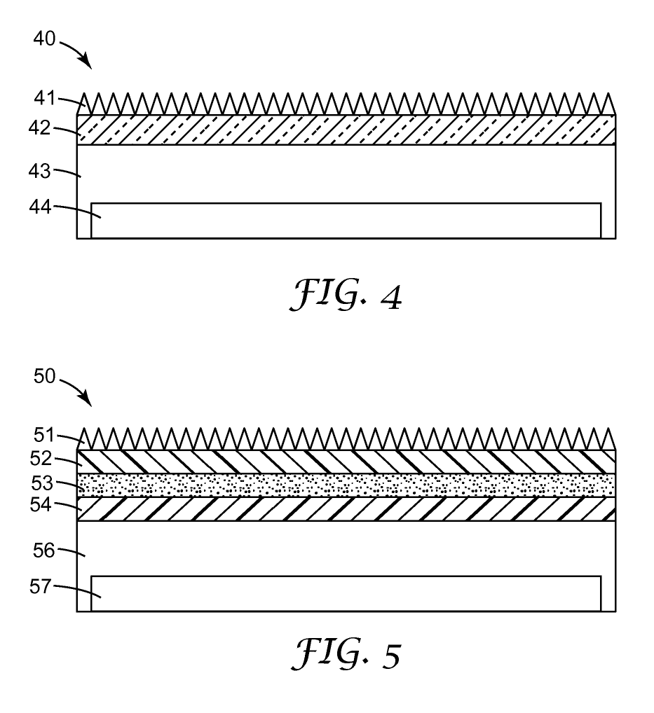

FIG. 4 shows another embodiment of the present application. Assembly 40 comprises a structured layer 41 that is adhered to a transparent substrate such as glass 42. An air gap 43 then exists, separating the structured layer 41 and glass 42 from the energy conversion device 44. FIG. 5 shows another embodiment of this application, wherein the assembly 50 comprises a structured surface 51 on a film layer 52, which is adhered to another film layer 54 using adhesive layer 53 to form s structured assembly 55. The air gap 56 separated the structured assembly 55 from the energy conversion device 57. In such embodiments, the energy conversion device 44 and 57 may be a solar thermal device.

The energy conversion device, and especially the structured layer may be exposed to the outside environment, and are therefore susceptible to a variety of detrimental conditions. For example, exposure to the outside environment exposes the structured layer to the elements such as rain, wind, hail, snow, ice, blowing sand, and the like which can damage the structured surface. In addition, long term exposure to heat and UV exposure from the sun can also cause degradation of the structured layer. Polymeric organic materials are susceptible to breakdown upon repeated exposure to UV radiation.

Weatherability for devices such as a solar energy conversion device is generally measured in years, because it is desirable that the materials be able to function for years without deterioration or loss of performance. It is desirable for the materials to be able to withstand up to 20 years of outdoor exposure without significant loss of optical transmission or mechanical integrity. Typical polymeric organic materials are not able to withstand outdoor exposure without loss of optical transmission or mechanical integrity for extended periods of time, such as 20 years.

Typically the structured polyurethane layer comprises an aliphatic polyurethane because polyurethanes that contain aromatic molecules can yellow over time due to exposure to UV radiation. Additionally, at least one UV stabilizer is present in the structured polyurethane layer to further enhance the weatherability. In some embodiments a combination of UV stabilizers is used.

### EXAMPLES

These examples are merely for illustrative purposes only and are not meant to be limiting on the scope of the appended claims. All parts, percentages, ratios, etc. in the examples and the rest of the specification are by weight, unless noted otherwise.

### Example 1

A polypropylene microstructured surface film with one surface having a “riblet” pattern of linear prisms with 53° apex angle was wrapped around a three inch core. A blend of UV absorbers commercially available from Ciba Specialty Chemicals, Tarrytown, N.Y. (2.0 wt. % “TINUVIN 405” and 1.0% wt “TINUVIN 123”) and dibutyl tin dilaurate catalyst (0.03 wt % commercially available from Air Products, Allentown, Pa. under the trade designation “DABCO T12”) were pre-dissolved in KFLEX 188 polyol (commercially available from King Industries, Inc. of Norwalk, Conn. under the trade designation “KFLEX 188”) at 40° C. 28 g of this mixture and 22 g hexamethylene diisocyante (commercially available from Bayer MaterialScience AG, of Leverkusen, Germany under the trade designation “DESMODUR N3300”, dimer and trimer of hexamethylene diisocyanate with 2.4 avg. isocyanate) were hand stirred in a plastic beaker. All ingredients were preheated to 40° C. The weight % of UV absorbers and catalyst were based on the KFLEX 188 and Desmodur 3300 and additives. The leading end of the polypropylene tooling film was squared and taped down to the edge of a photovoltaic panel. The flowable material was dispensed to form a small bank of polyurethane in front of the tooling film. Hand pressure sufficient to spread the curable resin was applied to a coating bar over the length of the tooling film. The polyurethane was allowed to cure in an oven for 30 minutes at 150° F. Once the polyurethane was cured, and the panel cooled back to room temperature, the tooling film was removed to expose the newly formed microstructured surface on the substrate. Application of the “KFLEX 188” “riblet” structure directly to a piece of glass lowered the percent reflection from 4.19% to 0.43%.

### Measurement of Average % Reflectance

The average % reflectance of the plasma treated surface was measured using PerkinElmer Lambda 950 UV-VIS-NIR Scanning Spectrophotometer. One sample of each film was prepared by applying Yamato Black Vinyl Tape #200-38 (obtained from Yamato International Corporation, Woodhaven, Mich.) to the backside of the sample. Clear poly (methyl methacrylate) (PMMA) film of which transmission and reflectance from both sides were predetermined was utilized to establish the reflectance from the black tape. The black tape was laminated to the backside of the sample using a roller to ensure there were no air bubbles trapped between the black tape and the sample. To measure the front surface total reflectance (specular and diffuse) by an integrating sphere detector, the sample was placed in the machine so that the non-tape side was against the aperture. The reflectance was measured at an 8° incident angle and average % reflectance was calculated by subtracting the reflectance of the black tape for the wavelength range of 400-800 nm.

### Example 2

A mixture of aliphatic polyester polyol Kflex 188 (King Industries) and a polyisocyanate based on hexamethylene diisocyante Desmodur N3300 (Bayer) with dibutyl tin dilaurate catalyst with 2% Tinuvin 405 UVA and 1% Tinuvin 123 HALS (as in Example 1) was applied to the front surface of a 50 watt photovoltaic module commercially available from AEE Solar (Redway, Calif.). A polypropylene film replication tool having prisms with 53 degree apex angles was rolled onto the surface of the mixture before it cured. After curing, the polypropylene prism film was removed leaving a micro-replicated surface structure on the cross-linked aliphatic urethane. The surface structured PV module was then aligned normal to the mid-day sun on a sunny day near the winter solstice in Scandia, Minn. Photovoltaic module power output was measured with a handheld voltage/current meter and calculated by multiplying open circuit voltage with closed loop current, and then multiplication again by a fill factor of 0.75, with the assumption that the fill factor was not changed by the structured surface film on the front side. PV power output was measured in the morning (9 AM), noon (12 PM), and afternoon (3 PM), and the results compared to a non-structured surface photovoltaic module control of the same make and model in Table 1.

TABLE 1

| | | Control (watts) | Example 2 (watts) | % Power Increase |
|---|---|---|---|---|
| 9 | AM | 35.2 | 38.3 | 8.7 |
| 12 | PM | 50.8 | 53.6 | 5.6 |
| 3 | PM | 24.6 | 28.0 | 13.7 |

### Example 3

A micro-replication casting tool was fabricated using a diamond with a 53-degree apex angle to cut a copper roll with linear prism grooves on a 100 micron pitch. This metal micro-replicating casting roll tool was then used to make a “riblet” 53 degree linear prism polypropylene polymer film tool with the same pattern by continuously extruding and quenching molten polypropylene on the metal casting roll tool.

Polyurethane films were prepared using a notched bar flatbed coating apparatus and the following procedure: A helical blade mixer was used to mix 1368 g of “KFLEX 188” with 288 g of Tinuvin 405, 144 g of Tinuvin 123 and 4.3 g of Dabco T12 for about 10 minutes. This polyol mixture was degassed in a vacuum oven at 60° C. for 15 hours, then loaded into plastic Part A dispensing cartridges and kept warm at 50° C. Desmodur N3300A was loaded into Part B dispensing cartridges and also kept warm at 50° C. A variable drive pump was set to have a volumetric ratio of Part A:Part B of 100:77. A 12″ long static mixer was used to blend the two components prior to coating. PMMA film was loaded onto the lower unwind and the PP riblet tooling film on the upper unwind. The films were coated at a line speed of 5 feet per minute (1.5 m/min). The heated platen oven had 5 zones, each 4 feet (1.2 m) long. The temperature of the first 4 zones was set to 160° F. (71° C.) while the last zone was at room temperature. The unwind tension for the top and bottom liners, and the rewind tension for the resultant coated film were all set to 20 lbs (89 N). The gap between the two liners at the nip formed by the notched bar and the flatbed was set to 3 mils (0.075 mm). After the film was coated and wound into a roll, it was conditioned at room temperature for at least 3 days prior to evaluation. After curing, the polypropylene tooling film was removed to produce a “riblet” micro-structured cross-linked polyurethane on a PMMA film.

ASTM D968-05e1 and ASTM D1003 were used to conduct the falling sand test and measure the % Transmission before and after the exposure to the falling sand. The three sample average before was 98.5% T and following the falling sand test was 89.7% T, a drop of 8.8% T.

The above described micro-structured film was then laminated to a glass slide using RTV silicone adhesive. Multilayer micro-structured laminate constructions were then exposed to e-beam radiation treatment as shown in Table I. These e-beamed multilayer laminate constructions were then exposed to Falling Sand abrasion testing as described by ASTM D968-05e1 Transmission changes in these e-beamed multilayer laminated constructions as measured per ASTM D1003 are also shown in Table 2.

TABLE 2

| | | | HazeGuard | | |
|---|---|---|---|---|---|
| e-beamed Kflex | | | Before | After | delta |
| Riblet | | | Falling Sand | Falling Sand | % |
| Sam- | e-beam conditions | | % Trans- | % Trans- | Trans- |
| ple | Voltage(kV) | Dose(Mrad) | mission | mission | mission |
| K1-1 | 110 | 10 | 99.1 | 94.5 | 4.6 |
| K1-2 | 110 | 10 | 99.1 | 95.2 | 3.9 |
| K1-3 | 110 | 10 | 99.1 | 94 | 5.1 |
| K2-1 | 110 | 20 | 99.5 | 95.8 | 3.7 |
| K2-2 | 110 | 20 | 99.5 | 96 | 3.5 |
| K2-3 | 110 | 20 | 99.5 | 95 | 4.5 |
| K3-1 | 110 | 30 | 98.5 | 96.6 | 1.9 |
| K3-2 | 110 | 30 | 98.5 | 96.7 | 1.8 |
| K3-3 | 110 | 30 | 98.5 | 95.6 | 2.9 |
| K4-1 | 120 | 10 | 99.5 | 97 | 2.5 |
| K4-2 | 120 | 10 | 99.5 | 97 | 2.5 |
| K4-3 | 120 | 10 | 99.5 | 95.2 | 4.3 |
| K5-1 | 120 | 20 | 99.2 | 96.3 | 2.9 |
| K5-2 | 120 | 20 | 99.2 | 95.2 | 4 |
| K5-3 | 120 | 20 | 99.2 | 96.8 | 2.4 |
| K6-1 | 120 | 30 | 99 | 97.3 | 1.7 |
| K6-2 | 120 | 30 | 99 | 96.6 | 2.4 |
| K6-3 | 120 | 30 | 99 | 96.7 | 2.3 |

A plot of these data is shown in FIG. 1.

### Example 4

The abrasion resistant anti-reflective film of example 3 is coated with alternating layers of silicon aluminum oxide and acrylate polymer onto one if its surfaces. The moisture barrier coated abrasion resistant anti-reflective film is expected to have a water vapor transmission rate of less than 0.005 grams/m² day at 50° C. under ASTM 1249ASTM1249.

### Example 5

The abrasion resistant anti-reflective moisture barrier film of example 4 is applied to a CIGS flexible photovoltaic cell. Another moisture barrier layer film such as aluminum foil is attached to the back side of the flexible photovoltaic cell with an enapsulant. The resulting flexible Copper Indium Gallium Selenide (CIGS) photovoltaic module is expected to last longer than 10 years.
Various modifications and alterations of the present invention will become apparent to those skilled in the art without departing from the spirit and scope of the invention.

What is claimed is:

1. An energy conversion assembly comprising:
a solar energy conversion device; and
a non-concentrating structured layer adjacent the energy conversion device, the structured layer comprising
a crosslinked reaction mixture comprising:
a polyol;
a polyisocyanate; and
a catalyst; and
at least one UV stabilizer.

2. The assembly of claim 1 wherein the structured layer has a structured surface, and the structured surface comprises the reaction mixture.

3. The assembly of claim 1 wherein the structured layer has a structured surface opposite the energy conversion device, and the structured surface is antireflective.

4. The assembly of claim 1 wherein the structured layer comprises a structured surface comprising a series of non-uniform structures.

5. The assembly of claim 4 wherein the structures average over the surface a slope of less than 30 degrees from normal.

6. The assembly of claim 1 wherein the structured layer comprises a structured surface comprising a series of structures, and the structures are substantially symmetric in one dimension around a perpendicular to the surface.

7. The assembly of claim 1 wherein the solar energy conversion device is a photovoltaic solar cell.

8. The assembly of claim 1 wherein the solar energy conversion device is a thermal absorption device.

9. The assembly of claim 1 wherein the structured layer is in contact with the energy device layer.

10. The assembly of claim 9 wherein the structured layer is cured directly on the energy device layer.

11. The assembly of claim 1 wherein the energy conversion device has a flat surface.

12. The assembly of claim 1 wherein the energy conversion device has a curved surface.

13. The assembly of claim 12 wherein the curved surface is a tube.

14. The assembly of claim 12 wherein the curved surface encompasses a solar energy conversion device.

15. The assembly of claim 1 wherein the structured layer comprises an aliphatic polyurethane.

16. The assembly of claim 1 wherein the at least one UV stabilizer is selected from a UV Absorber (UVA), a Hindered Amine Light Stabilizer (HALS), an antioxidant or combinations thereof.

17. The assembly of claim 1 wherein the UV stabilizer comprises triazines.

18. The assembly of claim 1 wherein the structured layer further comprises at least one additional additive selected from particles, antimildew agents, antifungal agents, antifoaming agents, antistatic agents, coupling agents, release agents, antisoiling agents, and combinations thereof.

19. The assembly of claim 1 wherein the structured layer comprises a structured surface comprising a series of structures, and the structures have an apex angle of less than 60 degrees.

20. The assembly of claim 1 wherein the structured layer comprises a structured surface comprising a series of structures, and the structures have an apex angle of less than 50 degrees.

21. The assembly of claim 1 wherein the structured layer comprises a structured surface comprising a series of structures, and the structures have an apex angle of less than 40 degrees.

22. The assembly of claim 1 wherein the polyol comprises a cyclohexanol unit.

23. The assembly of claim 22 wherein the cyclohexanol unit is cyclohexanedimethanol.

24. The assembly of claim 1 wherein the non-concentrating structured layer has a higher crosslink density at the surface of the film surface.

25. The assembly of claim 1 wherein the non-concentrating structured layer is coated with moisture barrier coatings

26. The assembly of claim 25 where the moisture barrier coated non-concentrating structured layer is attached to a photovoltaic cell.

27. The assembly of claim 7 wherein the photovoltaic cell is attached to an automobile, a plane, a train, a boat, a recreational means of transportation or a human-powered vehicle.
